(19) United States
(12) Patent Application Publication
(10) Pub. No.: US 2026/0344517 A1
(43) Pub. Date: Oct. 29, 2026

(54) STIFFENER AND SEMICONDUCTOR PACKAGE INCLUDING THE SAME

(71) Applicant: Samsung Electronics Co., Ltd., Suwon-si (KR)

(72) Inventors: Junbae Kim, Suwon-si (KR); Seok-Hong Kwon, Suwon-si (KR)

(21) Appl. No.: 19/371,783

(22) Filed: Oct. 28, 2025

(30) Foreign Application Priority Data
Apr. 24, 2025 (KR) 10-2025-0053793

(51) Int. Cl. H10W 90/00; H10D 1/68; H10W 76/47; H10W 74/15

(52) U.S. Cl. CPC H10W 90/00; H10D 1/714; H10D 1/716; H10W 76/47; H10W 90/701; H10W 74/15; H10W 90/724; H10W 90/734

(57) ABSTRACT

A semiconductor package includes: a substrate including a plurality of pads, a semiconductor chip structure attached to the substrate through a plurality of interconnection structures on the substrate, and electrically connected to the plurality of pads, and a stiffener attached to the substrate on the substrate and comprising a plurality of capacitors including a first electrode and a second electrode connected to a plurality of bonding wires. A height of the stiffener is equal to a height of the semiconductor chip structure.

### CROSS-REFERENCE TO RELATED APPLICATION

This application claims priority to and the benefit of Korean Patent Application No. 10-2025-0053793 filed with the Korean Patent Office on Apr. 24, 2025, the entire contents of which are incorporated herein by reference.

### BACKGROUND

As semiconductor chips become more high-performance, their frequencies may become faster and more noise is generated. Additionally, as noise increases, the loss of power supplied inside the semiconductor chip may increase.

In addition, semiconductor packages containing semiconductor chips are manufactured with a thin thickness, so they are very vulnerable to external physical stresses such as warpage.

### SUMMARY

The present disclosure relates to a stiffener and a semiconductor package including the same.

Some implementations relate to a stiffener including a capacitor and a semiconductor package including the same.

Some implementations relate to a stiffener for optimizing the size of a semiconductor package and a semiconductor package including the same.

In some implementations, a semiconductor package comprises: a substrate including a plurality of pads, a semiconductor chip structure attached to the substrate through a plurality of interconnection structures on the substrate, and electrically connected to the plurality of pads, and a stiffener attached to the substrate on the substrate and comprising a plurality of capacitors including a first electrode and a second electrode connected to a plurality of bonding wires, wherein a height of the stiffener is equal to a height of the semiconductor chip structure, and the plurality of capacitors are electrically connected to the plurality of pads through the plurality of bonding wires.

In some implementations, a semiconductor package comprises: a substrate, a semiconductor chip structure attached to the substrate through a plurality of first interconnection structures on the substrate, and a stiffener attached to the substrate on the substrate and configured to mechanically support the substrate, the stiffener comprising a first layer and a second layer on the first layer including a material having the same coefficient of thermal expansion as the substrate, and the stiffener comprising a plurality of capacitors in the first layer and the second layer.

In some implementations, a stiffener comprises: a first layer including a silicon wafer, a second layer on the first layer, wherein the stiffener defines a trench that extends into at least a portion of the first layer and at least a portion of the second layer, and a silicon capacitor including a first electrode in the trench, a dielectric layer on the first electrode, and a second electrode on the dielectric layer.

### BRIEF DESCRIPTION OF THE DRAWINGS

FIG. 1 is a perspective view of a semiconductor package according to some implementations.

FIG. 2 is a cross-sectional view taken along line A-A' of FIG. 1.

FIG. 3 is a cross-sectional view taken along line B-B' of FIG. 1.

FIG. 4 is a cross-sectional view showing the upper surface of a stiffener according to some implementations.

FIG. 5 is a cross-sectional view showing the upper surface of a stiffener according to some implementations.

FIG. 6 is a perspective view of a semiconductor package according to some implementations.

FIG. 7 is a cross-sectional view taken along line C-C' of FIG. 6.

FIG. 8 is a perspective view of a semiconductor package according to some implementations.

FIG. 9 is a cross-sectional view taken along line D-D' of FIG. 8.

FIG. 10 is a perspective view of a semiconductor package according to some implementations.

FIG. 11 is a cross-sectional view taken along line E-E' of FIG. 10.

FIG. 12 is a perspective view of a semiconductor package according to some implementations.

FIG. 13 is a perspective view of a semiconductor package according to some implementations.

### DETAILED DESCRIPTION

Below, with reference to the attached drawings, an implementation of the present disclosure is described in detail so that a person having ordinary skill in the art to which the present disclosure pertains may easily practice the present disclosure. However, the present disclosure may be implemented in various different forms and is not limited to the implementations described herein.

And in order to clearly explain the present disclosure in the drawings, parts unrelated to the explanation are omitted, and similar parts are given similar drawing reference numerals throughout the specification. In the flowchart described with reference to the drawings, the order of operations may be changed, several operations may be merged, some operations may be split, and certain operations may not be performed.

Additionally, expressions written in the singular may be interpreted as singular or plural, unless explicit expressions such as "one" or "singular" are used. Terms that include ordinal numbers, such as first, second, etc., may be used to describe various components, but the components are not limited by these terms. These terms may be used to distinguish one component from another.

As discussed above, as semiconductor chips become more high-performance, their frequencies may become faster and more noise is generated. Additionally, as noise increases, the loss of power supplied inside the semiconductor chip may increase. This problem may be solved by forming capacitors around the semiconductor chip. In addition, semiconductor packages containing semiconductor chips are manufactured with a thin thickness, so they are very vulnerable to external physical stresses such as warpage. This problem may be solved by using stiffeners located around the semiconductor chip.

However, when capacitors and stiffeners are placed separately around the semiconductor chip to address its physical and electrical issues, the overall size of the semiconductor package may increase due to the area occupied by the capacitors and stiffeners.

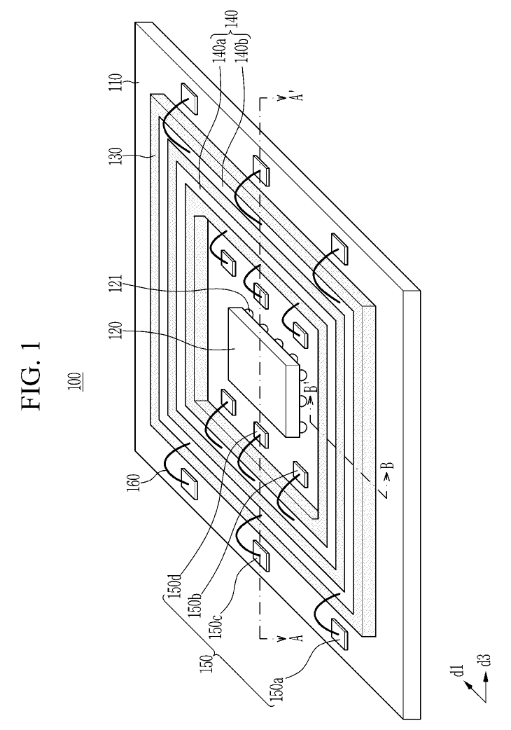

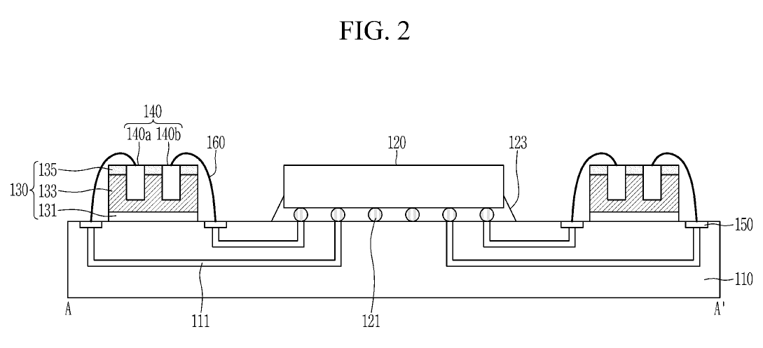

Aspects of the present disclosure address the above-discussed issues in the related art. FIG. 1 is a perspective view of a semiconductor package according to some implementations, and FIG. 2 is a cross-sectional view taken along line A-A' of FIG. 1.

Referring to FIG. 1 and FIG. 2, a semiconductor package 100 may include a substrate 110, a semiconductor chip structure 120, and a stiffener 130.

A semiconductor chip structure 120 may be placed on a substrate 110. The semiconductor chip structure 120 may be attached to the substrate 110 through interconnection structures 121 (e.g., a micro bump or solder bump, etc.). The semiconductor chip structure 120 may be physically and electrically connected to the substrate 110 through the interconnection structures 121. The semiconductor chip structure 120 may be electrically connected to the wire (111 of FIG. 2) inside the substrate 110 through the interconnection structures 121. The semiconductor chip structure 120 may receive electrical signals from the outside or output electrical signals to the outside through the interconnection structures 121 and the wire 111 inside the substrate 110. The wire 111 may include at least one metal or an alloy including two or more metals among copper Cu, aluminum Al, nickel Ni, silver Ag, gold Au, platinum Pt, tin Sn, lead Pb, titanium Ti, chromium Cr, palladium Pd, indium In, zinc Zn, and carbon C.

The semiconductor chip structure 120 may be an IC chip in which a plurality of integrated circuits ICs are formed on a wafer. The semiconductor chip structure 120 may include, for example, a logic chip such as a central processing unit CPU, a graphic processing unit GPU, a field programmable gate array FPGA, a digital signal processor, a cryptographic processor, a microprocessor, a microcontroller, an analog-to-digital converter, an application-specific IC ASIC, or a memory chip such as a volatile memory (e.g., DRAM), a non-volatile memory (e.g., ROM), or a flash memory. The semiconductor package 100 may further include an underfill (123 of FIG. 2) that fills the space between the substrate 110 and the semiconductor chip structure 120 and surrounds the interconnection structures 121. The underfill 123 may be formed using, for example, an epoxy resin, a benzocyclobutene resin, or a polyimide resin.

In some implementations, the substrate 110 may include a plurality of pads 150. A plurality of pads 150 may be spaced apart from each other at a predetermined interval on the substrate 110. Here, it is illustrated that a plurality of pads 150 are arranged spaced apart from the semiconductor chip structure 120 in a first direction and a second direction opposite to the first direction, but it is not limited thereto. In some implementations, the number of the plurality of pads 150 may vary.

Referring to FIG. 2, in some implementations, each of the plurality of pads 150 may be electrically connected to interconnection structures 121 through wire 111 within the substrate 110. Each of the plurality of pads 150 may be electrically connected to the semiconductor chip structure 120 through wire 111 and interconnection structures 121 inside the substrate 110. The semiconductor chip structure 120 may receive a voltage of a first polarity (e.g., a power supply voltage) and a voltage of a second polarity (e.g., a ground voltage) from the outside through interconnection structures 121. The semiconductor chip structure 120 may receive a voltage of a first polarity and a voltage of a second polarity from the outside through some of the interconnection structures 121. Each of the plurality of pads 150 may be electrically connected to interconnection structures 121 that provides a voltage of a first polarity and a voltage of a second polarity through wire 111 inside the substrate 110.

Referring to FIG. 1, a stiffener 130 may be placed on a substrate 110. The stiffener 130 may be arranged on the substrate 110 to surround the side of the semiconductor chip structure 120. The upper surface of the stiffener 130 may be positioned at substantially the same level as or lower than the upper surface of the semiconductor chip structure 120. The height of the stiffener 130 may be substantially the same as or lower than the height of the semiconductor chip structure 120. In some implementations, the stiffener 130 may surround at least a portion of the semiconductor chip structure 120 around the semiconductor chip structure 120. For example, the stiffener 130 may surround the semiconductor chip structure 120 around the semiconductor chip structure 120 in a first direction (d1) and a third direction (d3) perpendicular to the first direction (d1). Here, the stiffener 130 is illustrated as having a square ring shape surrounding the semiconductor chip structure 120, but the shape of the stiffener 130 is not limited thereto. For example, the stiffener 130 may have any other suitable shape (e.g., circle, rectangle, oval, pentagon, hexagon, octagon) surrounding the semiconductor chip structure 120. The stiffener 130 may improve the thermal properties of the substrate 110, such as the warpage properties of the substrate 110, by mechanically supporting the substrate 110.

In some implementations, the stiffener 130 may be formed of silicon. The stiffener 130 may be formed from a silicon wafer. The stiffener 130 may be formed by cutting a silicon wafer. The stiffener 130 may be formed of substantially the same material as the substrate 110. For example, the stiffener 130 may be formed of a silicon wafer having substantially the same coefficient of thermal expansion CTE as the substrate 110 and high thermal conductivity. Referring to FIG. 2, the stiffener 130 may include a silicon layer 133 formed from a silicon wafer. The stiffener 130 may be mechanically bonded or attached to the substrate 110 using an adhesive 131. The stiffener 130 may include a passivation layer 135 formed on a silicon layer 133. The passivation layer 135 may be formed of an insulator. For example, the passivation layer 135 may be formed of silicon nitride, silicon oxynitride, silicon carbon nitride, a polymer, another material, or a combination thereof.

In some implementations, the stiffener 130 may include a plurality of capacitors 140 contained in trenches formed by etching a silicon wafer. The stiffener 130 may include a plurality of capacitors 140 positioned in trenches that penetrate at least a portion of the passivation layer 135 and at least a portion of the silicon layer 133. A plurality of capacitors 140 included in a trench formed by etching the passivation layer 135 and the silicon layer 133 of the stiffener 130 may be silicon capacitors.

Referring to FIG. 1, in some implementations, a plurality of capacitors 140 may extend along the stiffener 130 within the stiffener 130. A plurality of capacitors 140 may extend in a square ring shape surrounding the semiconductor chip structure 120 within the stiffener 130. A plurality of capacitors 140 may be electrically connected to a plurality of pads 150 via bonding wires 160. For example, a first capacitor 140a among the plurality of capacitors may be electrically connected to a plurality of pads through a bonding wire 160, and a second capacitor 140b among the plurality of capacitors may be electrically connected to a plurality of pads through a bonding wire 160. A plurality of capacitors 140 may operate as capacitors when voltages of different polarities are applied to each capacitor.

In some implementations, the plurality of capacitors 140 may each be applied with voltages of different polarities through the bonding wires 160 and the plurality of pads 150. For example, the first capacitor 140a may receive a voltage of the first polarity through the bonding wire 160 and the first pad 150b, and may receive a voltage of the second polarity through the bonding wire 160 and the second pad 150d. Alternatively, the second capacitor 140b may receive a voltage of the first polarity through the bonding wire 160 and the third pad 150a, and may receive a voltage of the second polarity through the bonding wire 160 and the fourth pad 150c.

In some implementations, a plurality of capacitors 140 may be electrically connected to the interconnection structures 121 that is electrically connected to a semiconductor chip structure 120 via bonding wires 160 and a plurality of pads 150. Specifically, a plurality of capacitors 140 may be electrically connected to the interconnection structures 121 that provides a voltage of a first polarity and a voltage of a second polarity to a semiconductor chip structure 120 through bonding wires 160 and a plurality of pads 150. For example, a first capacitor 140a may be electrically connected to the interconnection structures 121 that provides a voltage of a first polarity and a voltage of a second polarity to a semiconductor chip structure 120 through a bonding wire 160 and a plurality of pads 150. In some implementations, the second capacitor 140b may be electrically connected to the interconnection structures 121 that provides a voltage of the first polarity and a voltage of the second polarity to the semiconductor chip structure 120 through a bonding wire 160 and a plurality of pads 150.

According to a comparative example, a semiconductor package includes a plurality of die side capacitors arranged around a semiconductor chip structure. A semiconductor package according to a comparative example ensures power integrity PI characteristics of a semiconductor chip structure through a die-side capacitor.

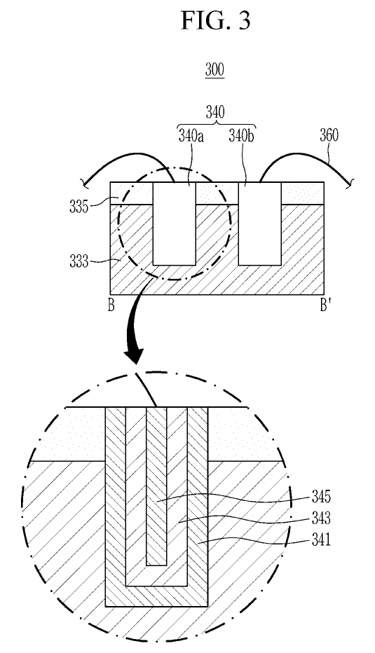

A semiconductor package according to some implementations includes a stiffener 130 including a plurality of capacitors 140. A semiconductor package 100 according to some implementations may strengthen the physical characteristics of the semiconductor package 100 through a stiffener 130 while ensuring the power integrity characteristics of the semiconductor chip structure 120 through a capacitor 140 formed within the stiffener 130. In some implementations, there is an advantage in that the size of the semiconductor package 100 may be reduced by eliminating the die-side capacitor. A specific description of the capacitor 140 formed in the stiffener 130 will be described later with reference to FIG. 3.

FIG. 3 is a cross-sectional view taken along line B-B' of FIG. 1. Specifically, FIG. 3 is a drawing for explaining a capacitor within a stiffener according to some implementations.

In some implementations, the stiffener 300 may include a silicon layer 333 formed from a silicon wafer and may include a passivation layer 335 formed on the silicon layer 333. In some implementations, the stiffener 300 may include a plurality of capacitors 340. The stiffener 300 may include a plurality of capacitors 340 included in trenches formed by etching a silicon layer 333 and a passivation layer 335.

In some implementations, the capacitor 340 may include a first electrode 341, a dielectric layer 343, and a second electrode 345. A first electrode 341, a dielectric layer 343, and a second electrode 345 may be sequentially laminated in a trench formed by etching a silicon layer 333 and a passivation layer 335. Specifically, a first electrode 341 may be positioned on a trench formed by etching a silicon layer 333 and a passivation layer 335, a dielectric layer 343 may be positioned on the first electrode 341, and a second electrode 345 may be positioned on the dielectric layer 343. Accordingly, a dielectric layer 343 may be placed between the first electrode 341 and the second electrode 345. The first electrode 341 and the second electrode 345 are arranged to face each other with the dielectric layer 343 therebetween, so that they may operate as capacitors when voltages of different polarities are applied to the first electrode 341 and the second electrode 345. The first electrode 341, the dielectric layer 343, and the second electrode 345 may be exposed on the upper side of the stiffener 300.

In some implementations, the capacitor 340 may be applied with voltages of different polarities. For example, the first electrode 341 of the first capacitor 340a may be applied with a voltage of the first polarity, and the second electrode 345 may be applied with a voltage of the second polarity. Similarly, the second capacitor 340b may also be applied with a voltage of the first polarity and a voltage of the second polarity. The capacitor 340 may receive a voltage of a first polarity and a voltage of a second polarity from the outside through a bonding wire 360.

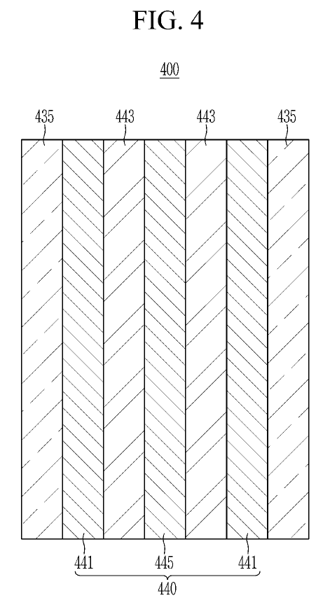

FIG. 4 is a cross-sectional view showing the upper surface of a stiffener according to some implementations.

Referring to FIG. 4, a stiffener 400 according to some implementations may include a passivation layer 435 and a capacitor 440 formed by etching a silicon layer under the passivation layer. A capacitor 440 may include a first electrode 441, a dielectric layer 443, and a second electrode 445. The first electrode 441 and the second electrode 445 are arranged to face each other with the dielectric layer 443 therebetween, so that they may operate as capacitors when voltages of different polarities are applied to the first electrode 441 and the second electrode 445.

In some implementations, the first electrode 441, the dielectric layer 443, and the second electrode 445 may extend in the same direction, and the first electrode 441, the dielectric layer 443, and the second electrode 445 may be formed uniformly in all sections. These capacitors 440 have the advantage of being simple in shape and thus easy to produce.

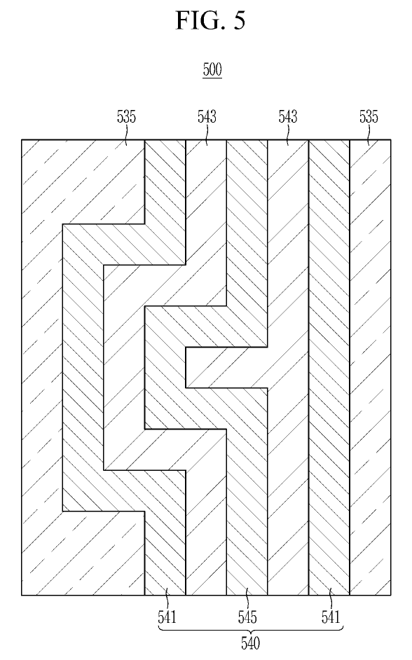

FIG. 5 is a cross-sectional view showing the upper surface of a stiffener according to some implementations.

Referring to FIG. 5, a stiffener 500 according to some implementations may include a passivation layer 535 and a capacitor 540 formed by etching a silicon layer under the passivation layer. A capacitor 540 may include a first electrode 541, a dielectric layer 543, and a second electrode 545. The first electrode 541 and the second electrode 545 are arranged to face each other with the dielectric layer 543 therebetween, so that they may operate as capacitors when voltages of different polarities are applied to the first electrode 541 and the second electrode 545.

In some implementations, the first electrode 541, the dielectric layer 543, and the second electrode 545 may be formed in a trench shape on the stiffener 500. Accordingly, the surface areas of the first electrode 541, the dielectric layer 543, and the second electrode 545 may increase. These capacitors 540 have the advantage of having a large electrostatic capacitance.

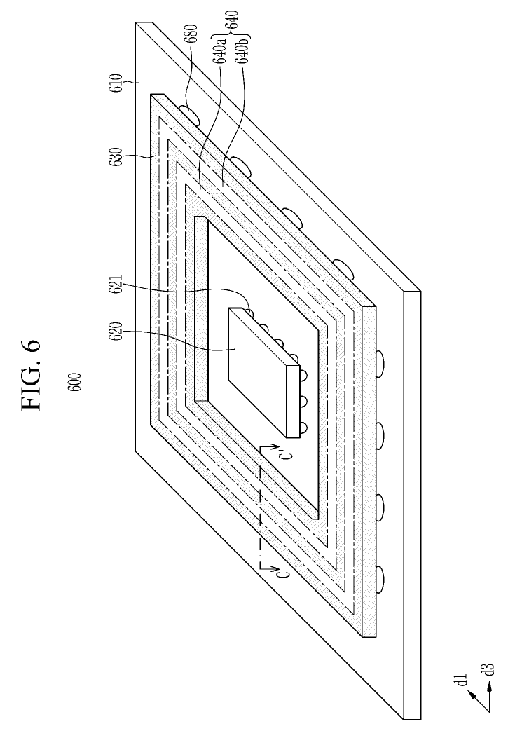

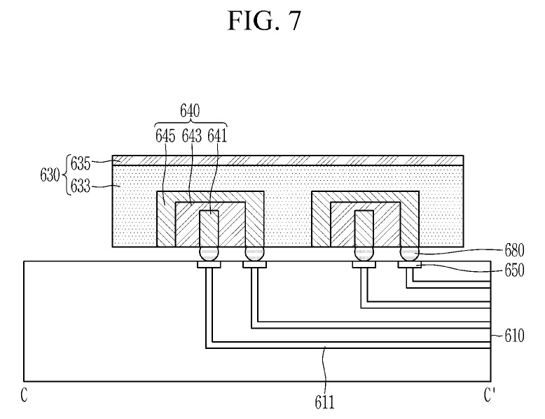

FIG. 6 is a perspective view of a semiconductor package according to some implementations, and FIG. 7 is a cross-sectional view taken along line C-C' of FIG. 6. For convenience of explanation, descriptions identical or similar to the semiconductor package 100 of FIG. 1 are omitted here.

Referring to FIG. 6, a semiconductor package 600 may include a substrate 610, a semiconductor chip structure 620, and a stiffener 630. A semiconductor chip structure 620 may be placed on a substrate 610 and physically and electrically connected to the substrate 610 through interconnection structures 621.

In some implementations, a stiffener 630 may be disposed on the substrate 610. In some implementations, the stiffener 630 may surround at least a portion of the semiconductor chip structure 620 around the semiconductor chip structure 620. For example, the stiffener 630 may surround the semiconductor chip structure 620 around the semiconductor chip structure 620 in a first direction (d1) and a third direction (d3) perpendicular to the first direction (d1). Here, the stiffener 630 is illustrated as having a square ring shape surrounding the semiconductor chip structure 620, but the shape of the stiffener 630 is not limited thereto. In some implementations, the stiffener 630 may be attached to the substrate 610 via the interconnection structures 680. The interconnection structures 680 herein may include, but is not limited to, bumps (e.g., micro bumps or solder bumps) or hybrid copper bonding. The interconnection structures 680 may be formed of a conductive material such as copper, aluminum, or the like. The stiffener 630 may be physically connected to the substrate 610 via the interconnection structures 680.

In some implementations, the stiffener 630 may include a plurality of capacitors 640 contained in trenches formed by etching a silicon layer within the stiffener 630. A plurality of capacitors 640 may include a plurality of electrodes and may operate as capacitors when voltages of different polarities are applied to the plurality of electrodes. Referring to FIG. 7, the stiffener 630 may include a silicon layer 633 and a passivation layer 635, and may include a plurality of capacitors 640 formed in trenches formed by etching the lower portion of the stiffener 630. The capacitor 640 may include a first electrode 641 positioned on a trench formed by etching a lower portion of a stiffener 630, a dielectric layer 643 positioned on the first electrode 641, and a second electrode 645 positioned on the dielectric layer 643. A capacitor 640 may include a first electrode 641 and a second electrode 645 positioned opposite each other with a dielectric layer 643 therebetween. The first electrode 641, the dielectric layer 643, and the second electrode 645 may be exposed at the bottom of the stiffener 630. Here, the capacitor 640 is illustrated as being formed by etching only the silicon layer 633, but is not limited thereto. For example, the capacitor 640 may extend to the passivation layer 635, and the second electrode 645 of the capacitor 640 may be exposed on top of the stiffener 630. In some implementations, the internal configuration of the capacitor 640 may be identical or similar to the configuration of the capacitor 340 described in FIG. 3.

In some implementations, a plurality of capacitors 640 may be connected to a plurality of interconnection structures 680. A plurality of capacitors 640 may be electrically connected to the substrate 610 via a plurality of interconnection structures 680. A plurality of capacitors 640 may be applied with different polarities through the interconnection structures 680. The interconnection structures 680 may apply voltages of different polarities to the plurality of capacitors 640. Referring to FIG. 7, the interconnection structures 680 may be attached to a pad 650 on a substrate 610 and electrically connect the first electrode 641 and the second electrode 645 within the stiffener 630 and the wire 611 within the substrate 610. A plurality of capacitors 640 may be applied with voltages of different polarities through the interconnection structures 680. For example, a plurality of capacitors 640 may be electrically connected to the plurality of pads 650 that provides a voltage of a first polarity and a voltage of a second polarity to a semiconductor chip structure 620 through interconnection structures 680 and wire 611 inside a substrate 610. Accordingly, the first electrode 641 in the capacitor 640 may be applied with a voltage of the first polarity, and the second electrode 645 may be applied with a voltage of the second polarity.

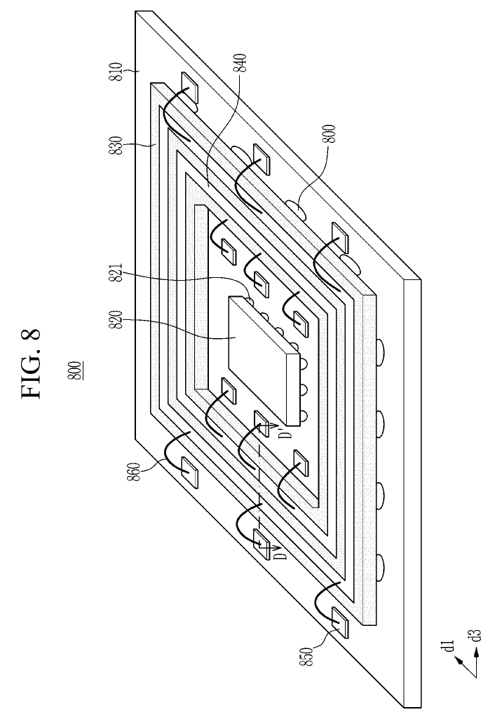

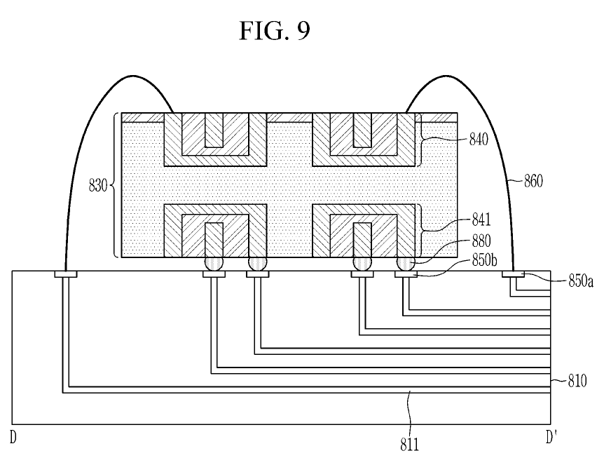

FIG. 8 is a perspective view of a semiconductor package according to some implementations, and FIG. 9 is a cross-sectional view taken along line D-D' of FIG. 8. For convenience of explanation, descriptions identical or similar to the semiconductor packages of FIG. 1 and FIG. 6 are omitted here.

Referring to FIG. 8, a semiconductor package 800 may include a substrate 810, a semiconductor chip structure 820, and a stiffener 830. A semiconductor chip structure 820 may be placed on a substrate 810 and physically and electrically connected to the substrate 810 through interconnection structures 821.

In some implementations, the substrate 810 may include a plurality of pads 850. A plurality of pads 850 may be spaced apart from each other at a predetermined interval on the substrate 810. Here, a plurality of pads 850 are illustrated as being spaced apart from the semiconductor chip structure 820 in a first direction and a second direction opposite to the first direction, but this is not limited thereto. In some implementations, the number of the plurality of pads 850 may vary.

In some implementations, a stiffener 830 may be disposed on the substrate 810. In some implementations, the stiffener 830 may surround at least a portion of the semiconductor chip structure 820 around the semiconductor chip structure 820. For example, the stiffener 830 may surround the semiconductor chip structure 820 around the semiconductor chip structure 820 in a first direction (d1) and a third direction (d3) perpendicular to the first direction (d1). Here, the stiffener 830 is illustrated as having a square ring shape surrounding the semiconductor chip structure 820, but the shape of the stiffener 830 is not limited thereto. Referring to FIG. 9, in some implementations, the stiffener 830 may be attached to the substrate 810 via the interconnection structures 880. The stiffener 830 may be physically connected to the substrate 810 via the interconnection structures 880.

In some implementations, the stiffener 830 may include a plurality of capacitors 840 contained in trenches formed by etching a silicon layer within the stiffener 830. The stiffener 830 may include a plurality of capacitors 840 included in trenches formed by etching an upper portion of the stiffener 830. In some implementations, the stiffener 830 may further include a plurality of capacitors contained in trenches formed by etching a lower portion of the stiffener 830. Referring to FIG. 9, a stiffener 830 according to some implementations may include an upper capacitor 840 included in a trench formed by etching an upper portion of the stiffener 830, and a lower capacitor 841 included in a trench formed by etching a lower portion of the stiffener 830. The internal configuration of the capacitor 840, 841 may be identical or similar to the configuration of the capacitor 340 described in FIG. 3.

In some implementations, the upper capacitor 840 may be electrically connected to a pad 850a on the substrate 810 via a bonding wire 860. Specifically, the upper capacitor 840 may receive voltages of different polarities through the wire 811 inside the substrate 810, pad 850a on the substrate 810, and bonding wire 860. In some implementations, the lower capacitor 841 may be electrically connected to a pad 850b on the substrate 810 via the interconnection structures 880. Specifically, the lower capacitor 841 may be applied with a voltage of a different polarity through the wire 811 inside the substrate 810, pad 850b on the substrate 810, and the interconnection structures 880. The upper capacitor 840 and the lower capacitor 841 are each supplied with voltages of different polarities and may operate as capacitors.

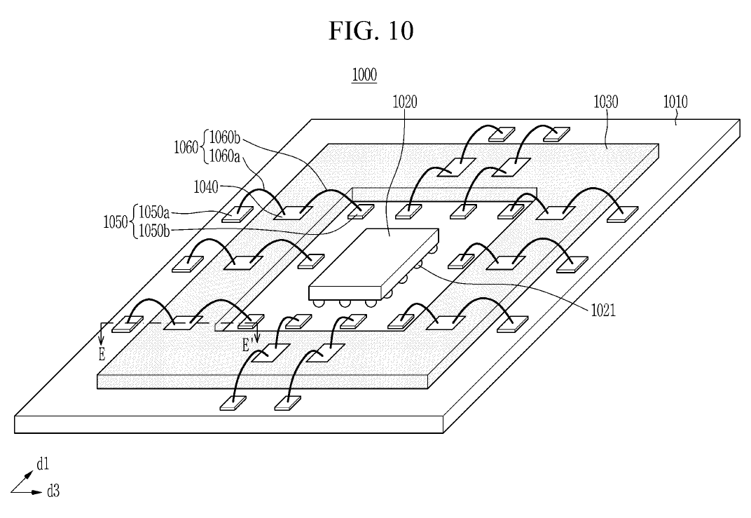

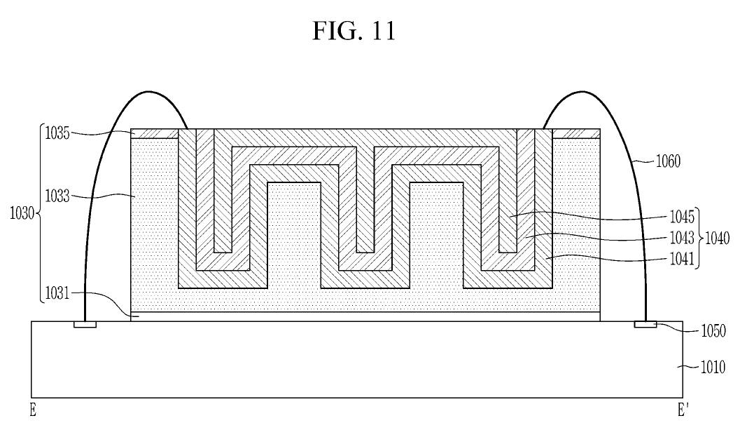

FIG. 10 is a perspective view of a semiconductor package according to some implementations, and FIG. 11 is a cross-sectional view taken along line E-E' of FIG. 10. For convenience of explanation, descriptions identical or similar to the semiconductor packages of FIGS. 1, 6, and 8 are omitted here.

Referring to FIG. 10, a semiconductor package 1000 may include a substrate 1010, a semiconductor chip structure 1020, and a stiffener 1030. A semiconductor chip structure 1020 may be placed on a substrate 1010 and may be physically and electrically connected to the substrate 1010 through interconnection structures 1021.

In some implementations, the substrate 1010 may include a plurality of pads 1050. A plurality of pads 1050 may be spaced apart from each other at a predetermined interval on the substrate 1010. Here, a plurality of pads 850 are illustrated as being spaced apart and arranged in a direction surrounding the semiconductor chip structure 820, but are not limited thereto. In some implementations, the number of the plurality of pads 1050 may vary.

In some implementations, a stiffener 1030 may be disposed on a substrate 1010. In some implementations, the stiffener 1030 may surround around at least a portion of the semiconductor chip structure 1020 around the semiconductor chip structure 1020. For example, the stiffener 1030 may surround the semiconductor chip structure 1020 around the semiconductor chip structure 1020 in a first direction (d1) and a third direction (d3) perpendicular to the first direction (d1). Here, the stiffener 1030 is illustrated as having a square ring shape surrounding the semiconductor chip structure 1020, but the shape of the stiffener 1030 is not limited thereto. Referring to FIG. 11, the stiffener 1030 may include an adhesive 1031, a silicon layer 1033, and a passivation layer 1035, and may be attached to the substrate 1010 via the adhesive 1031. The stiffener 1030 may be physically connected to the substrate 1010 via an adhesive 1031.

In some implementations, the stiffener 1030 may include a plurality of capacitors 1040 contained in trenches formed by etching a silicon wafer within the stiffener 1030. The stiffener 1030 may include a plurality of capacitors 1040 included in trenches formed by etching an upper portion of the stiffener 1030. In some implementations, the stiffener 1030 may include a plurality of capacitors 1040 that are separated from each other. A plurality of capacitors 1040 may be electrically connected to a plurality of pads 1050 on a substrate 1010 via bonding wires. For example, referring to FIG. 10, a capacitor 1040 may be electrically connected to a first pad 1050a via a first bonding wire 1060a and may be electrically connected to a second pad 1050b via a second bonding wire 1060b. The capacitor 1040 may receive voltages of different polarities through the first bonding wire 1060a and the second bonding wire 1060b.

Referring to FIG. 11, each capacitor 1040 may include a first electrode 1041, a dielectric layer 1043, and a second electrode 1045, and the plurality of electrodes 1041, 1045 may be electrically connected to a plurality of pads 1050 via bonding wires 1060. A plurality of electrodes 1041, 1045 may receive voltages of different polarities through bonding wires 1060 and a plurality of pads 1050. For example, the first electrode 1041 may be applied with a voltage of the first polarity, and the second electrode 1045 may be applied with a voltage of the second polarity.

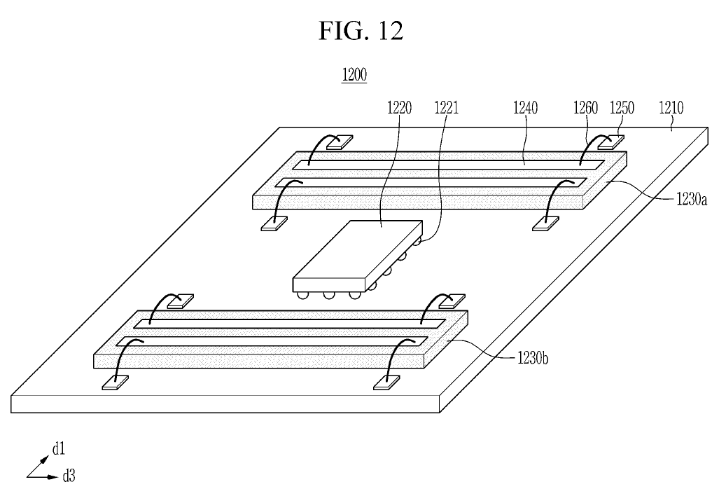

FIG. 12 is a perspective view of a semiconductor package according to some implementations. For convenience of explanation, descriptions identical or similar to the semiconductor packages of FIG. 1, FIG. 6, FIG. 8, and FIG. 10 are omitted here.

In some implementations, a semiconductor package 1200 may include a substrate 1210, a semiconductor chip structure 1220, and a plurality of stiffeners 1230a, 1230b. The semiconductor chip structure 1220 may be physically and electrically connected to the substrate 1210 through interconnection structures 1221.

In some implementations, a plurality of stiffeners 1230a, 1230b may be disposed on the substrate 1210. Referring to FIG. 12, each of the plurality of stiffeners 1230a, 1230b may be spaced apart from the semiconductor chip structure 1220 in a first direction (d1) and a second direction opposite to the first direction (d1). A plurality of stiffeners 1230a, 1230b may extend in a third direction (d3) perpendicular to the first direction (d1) on the substrate 1210. However, it is not limited to this. For example, each of the plurality of stiffeners 1230a, 1230b may be spaced apart from the semiconductor chip structure 1220 in a third direction (d3) and a fourth direction opposite to the third direction (d3), and may extend in a first direction (d1) on the substrate 1210. The upper surfaces of the plurality of stiffeners 1230a, 1230b may be positioned at substantially the same level as or lower than the upper surface of the semiconductor chip structure 1220. The height of the plurality of stiffeners 1230a, 1230b may be substantially the same as or lower than the height of the semiconductor chip structure 1220.

In some implementations, each of the plurality of stiffeners 1230a, 1230b may include a plurality of capacitors 1240. A plurality of capacitors 1240 may be electrically connected to the substrate 1210 via bonding wires 1260 and a plurality of pads 1250. A plurality of capacitors 1240 may be electrically connected to the interconnection structures 1221 via bonding wires 1260 and a plurality of pads 1250. A plurality of capacitors 1240 may receive voltages of different polarities through bonding wires 1260 and a plurality of pads 1250. The internal structure and connection structure of the plurality of capacitors 1240 may be identical to or similar to the internal structure and connection structure of the capacitors according to FIGS. 1 - FIG. 11.

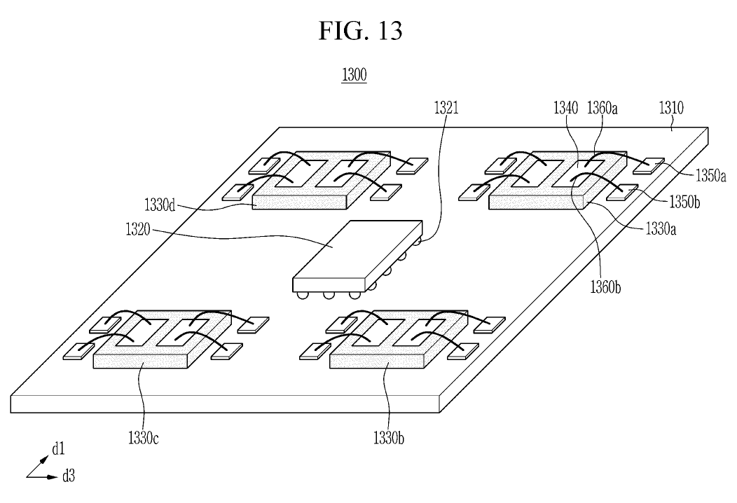

FIG. 13 is a perspective view of a semiconductor package according to some implementations. For convenience of explanation, descriptions identical or similar to the semiconductor packages of FIG. 1, FIG. 6, FIG. 8, and FIG. 10 are omitted here.

In some implementations, a semiconductor package 1300 may include a substrate 1310, a semiconductor chip structure 1320, and a plurality of stiffeners 1330a, 1330b, 1330c, 1330d. The semiconductor chip structure 1320 may be physically and electrically connected to the substrate 1310 through interconnection structures 1321.

In some implementations, a plurality of stiffeners 1330a, 1330b, 1330c, 1330d may be disposed on the substrate 1210. Referring to FIG. 13, each of the plurality of stiffeners 1330a, 1330b, 1330c, 1330d may be spaced apart from the semiconductor chip structure 1320 in the direction of an edge of the semiconductor chip structure 1320.

In some implementations, each of the plurality of stiffeners 1330a, 1330b, 1330c, 1330d may include a plurality of capacitors 1340. A plurality of capacitors 1340 may be electrically connected to the substrate 1310 via bonding wires 1360 and a plurality of pads 1350. A plurality of capacitors 1340 may be electrically connected to the interconnection structures 1321 via bonding wires 1360 and a plurality of pads 1350. A plurality of capacitors 1340 may receive voltages of different polarities through bonding wires 1360 and a plurality of pads 1350. For example, the capacitor 1340 may be applied with a voltage of a first polarity through the first bonding wire 1360a and the first pad 1350a, and the capacitor 1340 may be applied with a voltage of a second polarity through the second bonding wire 1360b and the second pad 1350b. The internal structure and connection structure of the plurality of capacitors 1340 may be identical to or similar to the internal structure and connection structure of the capacitors according to FIGS. 1 - FIG. 11.

As used herein, “about,” “approximately,” “generally,” and “substantially” are understood to refer to numbers in a range of numerals, for example the range of -10% to +10% of the referenced number, preferably -5% to +5% of the referenced number, more preferably -1% to +1% of the referenced number, most preferably -0.1% to +0.1% of the referenced number. Moreover, any numerical ranges disclosed herein should be interpreted as providing support for any specific value or sub-range within the stated range. For example, a disclosure of a range from 1 to 10 supports sub-ranges such as 1 to 5, 3 to 6, 1 to 9, 2.5 to 4.7, 2.2 to 9.9, and so on.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although the implementations of the present disclosure have been described in detail above, the scope of the present disclosure is not limited thereto, and various modifications and improvements made by those skilled in the art using the basic concept of the present disclosure defined in the following claims also fall within the scope of the present disclosure.

What is claimed is:

1. A semiconductor package comprising:
a substrate including a plurality of pads,
a semiconductor chip structure attached to the substrate through a plurality of interconnection structures on the substrate, and electrically connected to the plurality of pads, and
a stiffener attached to the substrate on the substrate and comprising a plurality of capacitors including a first electrode and a second electrode connected to a plurality of bonding wires, wherein a height of the stiffener is equal to a height of the semiconductor chip structure, and the plurality of capacitors are electrically connected to the plurality of pads through the plurality of bonding wires.

2. The semiconductor package of claim 1, wherein the stiffener comprises:
an adhesive configured to attach the stiffener to the substrate,
a silicon layer on the adhesive and including a silicon wafer, and
a passivation layer on the silicon layer and including an insulator.

3. The semiconductor package of claim 2, wherein the stiffener defines a trench that extends into at least a portion of the silicon layer and at least a portion of the passivation layer, wherein the plurality of capacitors are in the trench.

4. The semiconductor package of claim 3, wherein:
the plurality of capacitors comprise a dielectric layer, and
the first electrode is in the trench, the dielectric layer is on the first electrode, and the second electrode is on the dielectric layer.

5. The semiconductor package of claim 1, wherein:
the first electrode is electrically connected to a first interconnection structure, among the plurality of interconnection structures, through the plurality of bonding wires and the plurality of pads, wherein the first interconnection structure is configured to provide a first voltage to the semiconductor chip structure, and
the second electrode is electrically connected to a second interconnection structure, among the plurality of interconnection structures, through the plurality of bonding wires and the plurality of pads, wherein the second interconnection structure is configured to provide a second voltage different from the first voltage to the semiconductor chip structure.

6. The semiconductor package of claim 5, wherein the first voltage is a power supply voltage provided to the semiconductor chip structure, and the second voltage is a ground voltage provided to the semiconductor chip structure.

7. The semiconductor package of claim 1, wherein the stiffener is outside a periphery of at least a portion of the semiconductor chip structure.

8. The semiconductor package of claim 1,
wherein the stiffener comprises a first stiffener and a second stiffener,
wherein the first stiffener is spaced apart from the semiconductor chip structure in a first direction, and extends in a second direction perpendicular to the first direction, and
wherein the second stiffener is spaced apart from the semiconductor chip structure in a third direction opposite to the first direction, and extends in the second direction.

9. The semiconductor package of claim 1, wherein the plurality of capacitors are silicon capacitors.

10. A semiconductor package, comprising:
a substrate,
a semiconductor chip structure attached to the substrate through a plurality of first interconnection structures on the substrate, and
a stiffener attached to the substrate on the substrate and configured to mechanically support the substrate, the stiffener comprising a first layer and a second layer on the first layer including a material having the same coefficient of thermal expansion as the substrate, and the stiffener comprising a plurality of capacitors in the first layer and the second layer.

11. The semiconductor package of claim 10,
wherein the stiffener defines a trench in the first layer and the second layer,
wherein at least one of the plurality of capacitors comprises:
a first electrode on the trench in the first layer and the second layer,
a first dielectric layer on the first electrode, and
a second electrode on the first dielectric layer,
wherein the first electrode, the first dielectric layer, and the second electrode are exposed on an upper side of the stiffener.

12. The semiconductor package of claim 11, comprising:
a first bonding wire electrically connected to the first electrode,
a first pad attached on the substrate and configured to electrically connect the first bonding wire to a first-first interconnection structure among the plurality of first interconnection structures,
a second bonding wire electrically connected to the second electrode, and
a second pad attached on the substrate and configured to electrically connect the second bonding wire to a second-first interconnection structure among the plurality first interconnection structures.

13. The semiconductor package of claim 12, wherein:
the first electrode is configured to receive a first voltage through the first bonding wire and the first pad, and
the second electrode is configured to receive a second voltage different from the first voltage through the second bonding wire and the second pad.

14. The semiconductor package of claim 10, wherein the stiffener defines a trench in the first layer, wherein at least one of the plurality of capacitors comprises:
a third electrode on the trench in the first layer,
a second dielectric layer on the third electrode, and
a fourth electrode on the second dielectric layer,
wherein the third electrode, the second dielectric layer, and the fourth electrode are exposed on a lower side of the stiffener.

15. The semiconductor package of claim 14, comprising:
a plurality of second interconnection structures,
wherein a first-second interconnection structure among the plurality of second interconnection structures is configured to attach the stiffener to the substrate, is electrically connected to the third electrode, and is configured to apply a first voltage to the third electrode, and
a second-second interconnection structure among the plurality of second interconnection structures is configured to attach the stiffener to the substrate, is electrically connected to the fourth electrode, and is configured to apply a second voltage different from the first voltage to the fourth electrode.

16. The semiconductor package of claim 15, wherein the plurality of second interconnection structures are micro bumps.

17. The semiconductor package of claim 10, wherein the stiffener is outside a periphery of at least a portion of the semiconductor chip structure.

18. The semiconductor package of claim 10, wherein the first layer comprises a silicon wafer.

19. A stiffener, comprising:
a first layer including a silicon wafer,
a second layer on the first layer, wherein the stiffener defines a trench that extends into at least a portion of the first layer and at least a portion of the second layer,
and
a silicon capacitor including a first electrode in the trench, a dielectric layer on the first electrode, and a second electrode on the dielectric layer.

20. The stiffener of claim 19, comprising:
a first bonding wire connected to the first electrode, and
a second bonding wire connected to the second electrode.
